(19) United States
(12) Patent Application Publication
(10) Pub. No.: US 2007/0097655 A1
(43) Pub. Date: May 3, 2007

(54) LOAN STATUS REPORTING SYSTEM AND METHOD

(75) Inventors: Brian D. Yampolsky, Phoenix, AZ (US); Joseph R. Ashton, Phoenix, AZ (US)

Correspondence Address: SNELL & WILMER L.L.P. (Main), 400 EAST VAN BUREN, ONE ARIZONA CENTER, PHOENIX, AZ, 85004-2202, US

(73) Assignee: GET LOAN UPDATE, LLC, Phoenix, AZ (US)

(21) Appl. No.: 11/549,854

(22) Filed: Oct. 16, 2006

Related U.S. Application Data
(60) Provisional application No. 60/596,804, filed on Oct. 21, 2005.

(51) Int. Cl. H05K 1/14

(52) U.S. Cl. 361/737

(57) ABSTRACT

A system and method is disclosed for managing and communicating the tasks required in business and financial application processing and for reporting real-time application status. The system enables those involved in application processing to create client data, import client data from another application or database, add a task template based on the type of loan a borrower is seeking, receive notifications when a task requires their attention, and update the status of a task. The system further enables a borrower or any other authorized third party, including realtors and title agents among others, to access and view the status of their loan application. A gallery interface enables the borrower or any other authorized third-party to view photos of a property that borrower is purchasing.

### CROSS REFERENCE TO RELATED APPLICATIONS

This application claims priority to, and the benefit of, U.S. Provisional Application Ser. No. 60/596,804, filed Oct. 25, 2005 and entitled “Loan Status Reporting System and Method”, which is hereby incorporated by reference in its entirety.

### FIELD OF THE INVENTION

This invention generally relates to an online application management system, and more particularly, to a business process status reporting tool, wherein a number of in-process applications may be processed, monitored, and communicated internally and externally to determine the current status and to view next steps.

### BACKGROUND

Obtaining a mortgage for the purchase of a home or other property is known to be one of the most stressful experiences a borrower can experience. Therefore, mortgage lending institutions have often seek ways to reduce the burdens to the borrower and make the experience more pleasant. As competition within the mortgage lending industry has become increasingly intense, it is even more important to satisfy borrower needs. Mortgage lenders typically rely on quality customer service in order to encourage repeat business and generate positive word-of-mouth advertising.

Because loan processing is most often very complex and involves a large number of individual tasks, the opportunity for human error and forgotten tasks is high. Therefore, mortgage lenders have long sought sound processes and procedures to reduce the probability of mistakes. However, without a centralized repository for the management of loan processing tasks, reliance on personal communication through telephone, fax and email has grown. While such communication is key to helping to ensure that tasks are executed properly and in an efficient manner, it is again prone to error through miscommunication and/or forgotten tasks. Therefore, a need exists for a centralized system and method for managing loan processing tasks through the use of carefully defined business rules and automated communication tools. Further, there is a need to enable the borrower and third party professionals involved in a loan transaction to be updated on a regular basis as to the status of a pending loan, without fully relying on telephone updates from the lender.

### BRIEF DESCRIPTION OF THE DRAWINGS

A more complete understanding of the invention may be derived by referring to the detailed description and claims when considered in connection with the Figures, wherein like reference numbers refer to similar elements throughout the Figures, and:

FIG. 1 is a block diagram illustrating the major system components for an exemplary loan status reporting system in accordance with an embodiment of the present invention;

FIG. 2 is a screenshot of an exemplary interface for displaying a list of current pending loans and various links for managing loan processing information in accordance with an embodiment of the present invention;

FIG. 3 is a screenshot of an exemplary interface for displaying, entering and modifying loan information in accordance with an embodiment of the present invention;

FIG. 4 is a screenshot of an exemplary interface for uploading and displaying property photographs in accordance with an embodiment of the present invention;

FIG. 5 is a screenshot of an exemplary interface for displaying loan processing milestones and tasks in accordance with an embodiment of the present invention;

FIG. 6 is a screenshot of an exemplary interface for adding comments tied to a loan milestone for elaboration and informational purposes to internal and external third parties in accordance with an embodiment of the present invention;

FIG. 7 is a screenshot of an exemplary interface for displaying property information and photographs accessible by borrower designated third-parties in accordance with an embodiment of the present invention; and,

FIG. 8 is a screenshot of an exemplary interface for displaying a loan status checklist providing the ability to add custom “Ad Hoc” task descriptions specific to a particular transaction but not affecting the template for all transactions in accordance with an embodiment of the present invention.

### SUMMARY OF THE INVENTION

The invention includes a system, method and machine readable medium configured for processing and communicating business and financial applications in a workflow according to predefined rules and tasks. An interface to the system is provided via an internet browser application (and/or any other interface disclosed herein) and communications are exchanged electronically over the Internet or via any other known computer networking protocol.

In one embodiment, the loan processing system is secure and provides varying interfaces for those involved in, or those that need to know the status of loan application processing including, realtors, clients, title agents and any other third-party who is granted permission to interact with the system to participate in a processing workflow, view reports, and/or view the status of a loan application. For example, an employee of a mortgage lending company may be granted a set of permissions that allow the employee to view processing tasks, view task status, and update the status of a task. A client may be provided limited access to the system to view the status of the client's loan application.

The system includes a number of interfaces from which users may interact with the system at various levels. Such interfaces include, for example, pipeline reporting, loan management, photo gallery, loan status summary, and loan status. Preconfigured task templates enable loans of varying types to fully or partially follow a consistent workflow, while ensuring that critical tasks are completed in a timely manner. Workflow rules govern notification of responsible individuals when a task requires their attention, and in some embodiments, define next steps as tasks are completed.

### DETAILED DESCRIPTION OF EXEMPLARY EMBODIMENTS

The detailed description of exemplary embodiments of the invention herein describes the exemplary embodiment by way of illustration and its best mode. While these exemplary embodiments are described in sufficient detail to enable those skilled in the art to practice the invention, it should be understood that other embodiments may be realized and that logical and mechanical changes may be made without departing from the spirit and scope of the invention. Thus, the detailed description herein is presented for purposes of illustration only and not of limitation. For example, the steps recited in any of the method or process descriptions may be executed in any order and are not limited to the order presented.

For the sake of brevity, conventional data networking, application development and other functional aspects of the systems (and components of the individual operating components of the systems) may not be described in detail herein. Furthermore, the connecting lines shown in the various figures contained herein are intended to represent exemplary functional relationships and/or physical couplings between the various elements. It should be noted that many alternative or additional functional relationships or physical connections may be present in a practical system.

Many mortgage lenders heavily rely upon referrals from real estate professionals, including buyers' agents, sellers' agents, title companies, and past clients. When any of these individuals refer a client to a mortgage broker, the service that the client receives is a direct reflection on the referring party. The present invention is a loan process management system that allows these third party affiliates a behind the scenes look at how the loan is progressing. This eliminates or reduces the frustration of the involved parties who previously had little knowledge as to the status of a loan application, and subsequently provides for an improved lending experience. The client's view of the referring party may be enhanced by the professional image of all parties to the transaction, which is fostered by the invention.

For a mortgage lender to maintain professional and valuable relationships with other professionals in the industry, it seems reasonable to expect that the mortgage broker should give value back to these other professionals. The invention's update system accomplishes this by making third party professionals privy to this information as soon as it becomes available and without requiring them to call in and track down a loan officer. Furthermore, the “Client Gallery” aspect of the invention is specifically designed to obtain client endorsement for their realtors among other purposes. This effort is appreciated by many realtors and helps to strengthen the lender/realtor relationship. Because the professional image of the lender may be improved the implementation of the system of the invention, the referring parties may feel more comfortable referring additional clients to the lender.

While the system may apply to any processing system, a loan application processing and reporting system will be described herein in detail as an exemplary embodiment. In general, the invention includes a system and method for application status reporting. The invention facilitates management of any portion of financial and business application processing tasks from start to finish and includes a variety of tools useful for notifying those people, systems or entities in a processing workflow of upcoming tasks, as well as a notification feature to keep the client and any other third-parties updated as to the status of the application.

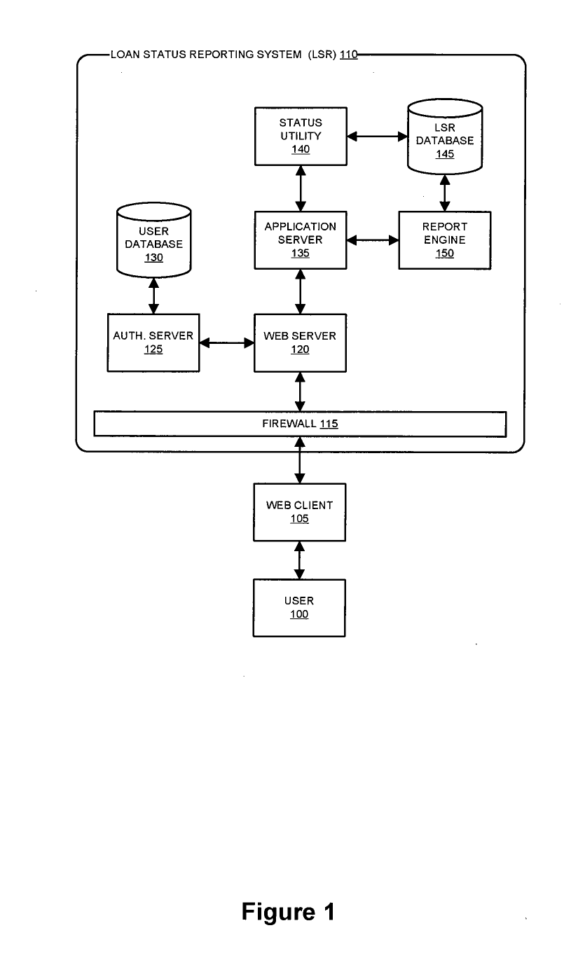

With reference to FIG. 1, in one embodiment, the system facilitates interaction between a user 100 and the Loan Status Reporting system (LSR) 110 through a web client 105. One skilled in the art will appreciate that LSR 110 is merely one exemplary embodiment of the system and method discussed herein. The invention contemplates a similar status reporting system for builders, title companies, realtors, brokers, bankers, wholesale lenders, appraisers, or any other individual, entity or service which includes management, processing and reporting of data by using business rules and multiple tasks. In exemplary embodiments, the rules may be configured to ensure compliance with regulatory and/or administrative requirements in one or more industries or jurisdictions.

Web client 105 is connected to a web server 120 through a network connection (e.g., Internet, Intranet, LAN, WAN and the like). Web server 105 may employ an authentication server 125 in order to validate and assign proper permissions to authorized users of the system. Permission database 130 stores user credentials and permissions specific to each user. Web server 120 also employs an application server 135 to manage various applications utilized by system 110. In exemplary embodiments, application server 135 may be a stand-alone server or may comprise software residing within web server 120.

In one embodiment, the status utility 140 is invoked by application server 135 to perform various tasks including querying the LSR database 145, generating electronic notifications, importing data from other systems, performing various calculations, and the like. While shown in FIG. 1 as connecting to status utility 140 through a web server, those skilled in the art will appreciate that web client 105 may connect with various components of LSR 110 either directly, or indirectly through another system component. To report loan status information, status utility 140 retrieves and stores data relating to any number of loans within LSR database 145. In one embodiment, status utility 140 interfaces with a report engine 150 to generate various views of data stored in LSR database 145. Report engine 150 further provides preconfigured and/or ad-hoc reports relating to one or more pending loans.

In addition to the components discussed above, LSR 110 may further include one or more of the following: a host server or other computing systems including a processor for processing digital data; a memory coupled to the processor for storing digital data; an input digitizer coupled to the processor for inputting digital data; an application program stored in the memory and accessible by the processor for directing processing of digital data by the processor; a display device coupled to the processor and memory for displaying information derived from digital data processed by the processor; and a plurality of databases. Various databases used herein may include: client data; asset data; enterprise data, loan data; financial institution data; and/or like data useful in the operation of the invention.

As will be appreciated by one of ordinary skill in the art, the invention may be embodied as a customization of an existing system, an add-on product, upgraded software, a standalone system (e.g., kiosk), a distributed system, a method, a data processing system, a device for data processing, and/or a computer program product. Accordingly, the invention may take the form of an entirely software embodiment, an entirely hardware embodiment, or an embodiment combining aspects of both software and hardware. Furthermore, the invention may take the form of a computer program product on a computer-readable storage medium having computer-readable program code means embodied in the storage medium. Any suitable computer-readable storage medium may be utilized, including hard disks, CD-ROM, optical storage devices, magnetic storage devices, and/or the like.

User 100 may include any individual, business, entity, government organization, software and/or hardware which interacts with LSR 110 to enter, edit and/or view information relating to one or more pending applications (e.g., loan applications). User 100 may be, for example, a loan processor. In one embodiment, the system may provide limited or restricted rights access for certain people or groups, such as, for example, realtors, clients, or any other third party with an interest in viewing loan status. A loan processor may interact with LSR 110 to enter and/or edit client information, check-off a task as being complete, advance the loan processing to a next step, generate status notifications, etc. A realtor may interact with LSR 110, on behalf of her client, in order to determine the current status of a mortgage loan. User 100 may interface with LSR 110 via any communications protocol, device or method discussed herein or known in the art. In one embodiment, user 100 may interact with the invention via an Internet browser at a web client 105.

Web client 105 may comprise any hardware and/or software suitably configured to facilitate input, receipt and/or review of any information related to LSR 110 or any information discussed herein. Web client 105 may include any device (e.g., personal computer), which communicates (in any manner discussed herein) with the invention via any network discussed herein. Such browser applications comprise Internet browsing software installed within a computing unit or system to conduct online transactions and communications. These computing units or systems may take the form of a computer or set of computers, although other types of computing units or systems may be used, including laptops, notebooks, hand held computers, set-top boxes, workstations, computer-servers, main frame computers, mini-computers, PC servers, pervasive computers, network sets of computers, and/or the like. Practitioners will appreciate that web client 105 may or may not be in direct contact with the LSR 110. For example, web client 105 may access the services of the LSR 110 through another server, which may have a direct or indirect connection to web server 120.

As those skilled in the art will appreciate, web client 105 may include an operating system (e.g., WINDOWS NT, 95/98/2000, OS2, UNIX, LINUX, SOLARIS, MACOS, etc.) as well as various conventional support software and drivers typically associated with computers. The web client 105 may include any suitable personal computer, network computer, workstation, minicomputer, mainframe or the like. Web client 105 can be in a home or business environment with access to a network. In an exemplary embodiment, access is through a network or the Internet through a commercially available web-browser software package.

Web client 105 may be independently, separately or collectively suitably coupled to the network via data links which includes, for example, a connection to an Internet Service Provider (ISP) as is typically used in connection with standard modem communication, cable modem, Dish networks, ISDN, Digital Subscriber Line (DSL), or various wireless communication methods, see, e.g., GILBERT HELD, UNDERSTANDING DATA COMMUNICATIONS (1996), which is hereby incorporated by reference. It is noted that the network may be implemented as other types of networks, such as an interactive television (ITV) network. Moreover, the system contemplates the use, sale or distribution of any goods, services or information over any network having similar functionality described herein.

The invention contemplates uses in association with web services, utility computing, pervasive and individualized computing, security and identity solutions, autonomic computing, commodity computing, mobility and wireless solutions, open source, service oriented architecture, biometrics, grid computing and/or mesh computing.

Web server 120 may include any hardware and/or software suitably configured to facilitate communications between web client 105 and one or more LSR 110 components. Further, web server 120 may be configured to transmit data to web client 105 within markup language documents. Web server 120 may operate as a single entity in a single geographic location or as separate computing components located together or in separate geographic locations. Requests originating from client browser 105 may pass through a firewall 115 before being received and processed at web server 120. As used herein, “transmit” may include sending electronic data from one system component to another over a network connection. Additionally, as used herein, “data” may include encompassing information such as commands, queries, files, data for storage, and the like in digital or any other form. Web server 120 may provide a suitable web site or other Internet-based graphical user interface which is accessible by users. In one embodiment, the Microsoft Internet Information Server (IIS), Microsoft Transaction Server (MTS), and Microsoft SQL Server, are used in conjunction with the Microsoft operating system, Microsoft NT web server software, a Microsoft SQL Server database system, and a Microsoft Commerce Server. Additionally, components such as Access or Microsoft SQL Server, ORACLE, SYBASE, INFORMIX MySQL, InterBase, etc., may be used to provide an Active Data Object (ADO) compliant database management system.

Any of the communications, inputs, storage, databases or displays discussed herein may be facilitated through a web site having web pages. The term “web page” as it is used herein is not meant to limit the type of documents and applications that might be used to interact with the user. For example, a typical web site might include, in addition to standard HTML documents, various forms, Java applets, JavaScript, active server pages (ASP), common gateway interface scripts (CGI), extensible markup language (XML), dynamic HTML, cascading style sheets (CSS), helper applications, plug-ins, and the like. A server may include a web service that receives a request from a web server, the request including a URL (http://yahoo.com/stockquotes/ge) and an IP address (123.56.789.98). The web server retrieves the appropriate web pages and sends the data or applications for the web pages to the IP address. Web services are applications that are capable of interacting with other applications over a communications means, such as the Internet. Web services are typically based on standards or protocols such as XML, SOAP, WSDL and UDDI. Web services methods are well known in the art, and are covered in many standard texts. See, e.g., ALEX NGHIEM, IT WEB SERVICES: A ROADMAP FOR THE ENTERPRISE (2003), hereby incorporated by reference.

In one embodiment, firewall 115 comprises any hardware and/or software suitably configured to protect LSR 110 components from users of other networks. Firewall 115 may reside in varying configurations including Stateful Inspection, Proxy based and Packet Filtering among others. Firewall 115 may be integrated as software within web server 120, any other system component or may reside within another computing device or may take the form of a standalone hardware component.

In one embodiment, applications server 135 includes any hardware and/or software suitably configured to serve applications and data to a connected web client 105. Like web server 120, applications server 135 may communicate with any number of other servers, databases and/or components through any means discussed herein or known in the art. Further, applications server 135 may serve as a conduit between web client 105 and LSR 110 and web client 105. Web server 120 may interface with applications server 135 through any means discussed herein or known in the art including a LAN/WAN, for example. Application server 135 may further invoke status utility 140 and/or report engine 150 in response to a user 100 request.

In one embodiment, report engine 150 includes any hardware and/or software suitably configured to produce reports from information stored in one or more databases. Report engines are commercially available and known in the art. Report engine 150 may provide printed reports, web access to reports, graphs, real-time information, raw data, batch information and/or the like. Report engine 150 may be implemented through commercially available hardware and/or software, through custom hardware and/or software components, or through a combination thereof. Further, report engine 150 may reside as a standalone system within LSR 110 or as a component of applications server 135 or web server 120.

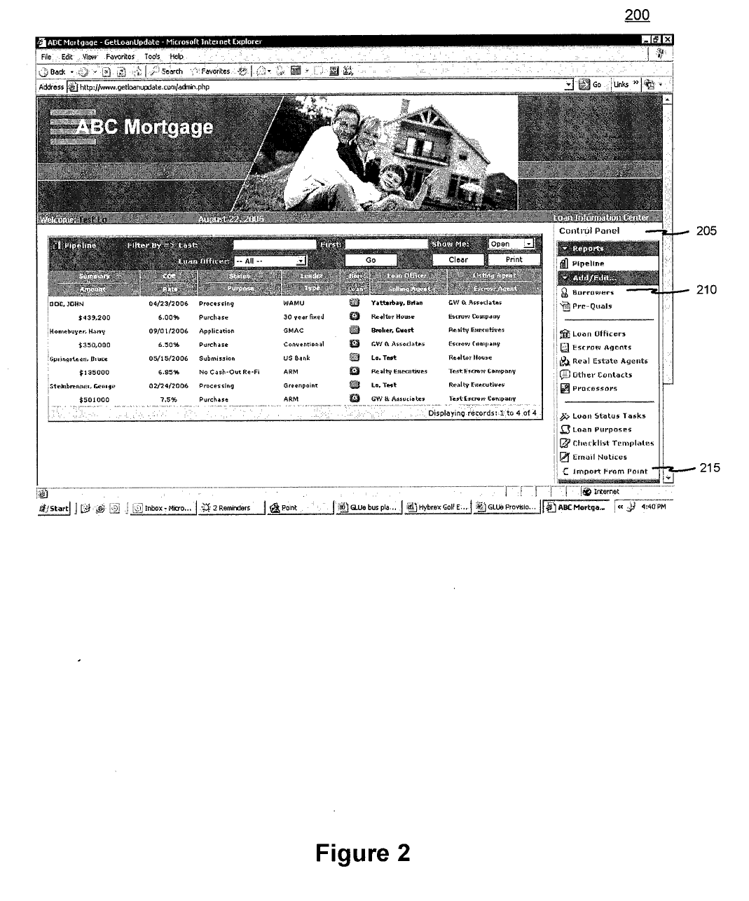

In one embodiment, status utility 140 includes any hardware and/or software suitably configured to carry out the steps described below in reference to FIGS. 2-7. Status utility 140 may exist as a standalone computing device or as a software entity stored within applications server 135 or web server 120. Status utility 140 may communicate directly or indirectly with one or more computing devices such as mainframe computers, for example. Further, status utility 140 may include business rules such as, for example, to define tasks as well as those responsible to execute the tasks during a pre-defined time period.

In order to control access to web server 120 or any other component of the invention, web server 120 may invoke an authentication server 125 in response to submission of user 100 authentication credentials received at web server 120. In one embodiment, authentication server 125 includes any hardware and/or software suitably configured to receive authentication credentials, encrypt and decrypt credentials, authenticate credentials, and grant access rights according to user 100 pre-defined privileges attached to the credentials. Authentication server 125 may grant varying degrees of application and data level access to user 100 based on user information stored within member user 130.

In one embodiment, user database 130 includes any hardware and/or software suitably configured to facilitate storing authentication and/or privilege information relating to users 100. LSR database 145 stores data relating to pending loan applications, clients, realtors, appraisal information, as well as any other related information as disclosed herein. One skilled in the art will appreciate that the invention may employ any number of databases in any number of configurations. Further, any databases discussed herein may be any type of database, such as relational, hierarchical, graphical, object-oriented, and/or other database configurations. Common database products that may be used to implement the databases include DB2 by IBM (White Plains, N.Y.), various database products available from Oracle Corporation (Redwood Shores, Calif.), Microsoft Access or Microsoft SQL Server by Microsoft Corporation (Redmond, Wash.), or any other suitable database product. Moreover, the databases may be organized in any suitable manner, for example, as data tables or lookup tables. Each record may be a single file, a series of files, a linked series of data fields or any other data structure. Association of certain data may be accomplished through any desired data association technique such as those known or practiced in the art. For example, the association may be accomplished either manually or automatically. Automatic association techniques may include, for example, a database search, a database merge, GREP, AGREP, SQL, using a key field in the tables to speed searches, sequential searches through all the tables and files, sorting records in the file according to a known order to simplify lookup, and/or the like. The association step may be accomplished by a database merge function, for example, using a “key field” in pre-selected databases or data sectors.

More particularly, a “key field” partitions the database according to the high-level class of objects defined by the key field. For example, certain types of data may be designated as a key field in a plurality of related data tables and the data tables may then be linked on the basis of the type of data in the key field. The data corresponding to the key field in each of the linked data tables is preferably the same or of the same type. However, data tables having similar, though not identical, data in the key fields may also be linked by using AGREP, for example. In accordance with one aspect of the invention, any suitable data storage technique may be utilized to store data without a standard format. Data sets may be stored using any suitable technique, including, for example, storing individual files using an ISO/IEC 7816-4 file structure; implementing a domain whereby a dedicated file is selected that exposes one or more elementary files containing one or more data sets; using data sets stored in individual files using a hierarchical filing system; data sets stored as records in a single file (including compression, SQL accessible, hashed via one or more keys, numeric, alphabetical by first tuple, etc.); Binary Large Object (BLOB); stored as ungrouped data elements encoded using ISO/IEC. 7816-6 data elements; stored as ungrouped data elements encoded using ISO/IEC Abstract Syntax Notation (ASN.1) as in ISO/IEC 8824 and 8825; and/or other proprietary techniques that may include fractal compression methods, image compression methods, etc.

In one exemplary embodiment, the ability to store a wide variety of information in different formats is facilitated by storing the information as a BLOB. Thus, any binary information can be stored in a storage space associated with a data set. As discussed above, the binary information may be stored on the financial transaction instrument or external to but affiliated with the financial transaction instrument. The BLOB method may store data sets as ungrouped data elements formatted as a block of binary via a fixed memory offset using either fixed storage allocation, circular queue techniques, or best practices with respect to memory management (e.g., paged memory, least recently used, etc.). By using BLOB methods, the ability to store various data sets that have different formats facilitates the storage of data associated with the invention by multiple and unrelated owners of the data sets. For example, a first data set which may be stored may be provided by a first party, a second data set which may be stored may be provided by an unrelated second party, and yet a third data set which may be stored, may be provided by an third party unrelated to the first and second party. Each of these three exemplary data sets may contain different information that is stored using different data storage formats and/or techniques. Further, each data set may contain subsets of data that also may be distinct from other subsets.

As stated above, in various embodiments of the invention, the data can be stored without regard to a common format. However, in one exemplary embodiment of the invention, the data set (e.g., BLOB) may be annotated in a standard manner when provided for manipulating the data onto the financial transaction instrument. The annotation may comprise a short header, trailer, or other appropriate indicator related to each data set that is configured to convey information useful in managing the various data sets. For example, the annotation may be called a “condition header”, “header”, “trailer”, or “status”, herein, and may comprise an indication of the status of the data set or may include an identifier correlated to a specific issuer or owner of the data. In one example, the first three bytes of each data set BLOB may be configured or configurable to indicate the status of that particular data set; e.g., LOADED, INITIALIZED, READY, BLOCKED, REMOVABLE, or DELETED. Subsequent bytes of data may be used to indicate for example, the identity of the issuer, user, transaction/membership account identifier or the like. Each of these condition annotations are further discussed herein.

The data set annotation may also be used for other types of status information as well as various other purposes. For example, the data set annotation may include security information establishing access levels. The access levels may, for example, be configured to permit only certain individuals, levels of employees, companies, or other entities to access data sets, or to permit access to specific data sets based on the transaction, merchant, issuer, user or the like. Furthermore, the security information may restrict/permit only certain actions such as accessing, modifying, and/or deleting data sets. In one example, the data set annotation indicates that only the data set owner or the user are permitted to delete a data set, various identified users may be permitted to access the data set for reading, and others are altogether excluded from accessing the data set. However, other access restriction parameters may also be used allowing various entities to access a data set with various permission levels as appropriate.

The data, including the header or trailer may be received by a standalone interaction device configured to create, update, delete or augment the data in accordance with the header or trailer. As such, in one embodiment, the header or trailer is not stored on the transaction device along with the associated issuer-owned data but instead the appropriate action may be taken by providing to the transaction instrument user at the standalone device, the appropriate option for the action to be taken. The invention may contemplate a data storage arrangement wherein the header or trailer, or header or trailer history, of the data is stored on the transaction instrument in relation to the appropriate data.

One skilled in the art will also appreciate that, for security reasons, any databases, systems, devices, servers or other components of the invention may consist of any combination thereof at a single location or at multiple locations, wherein each database or system includes any of various suitable security features, such as firewalls, access codes, encryption, decryption, compression, decompression, and/or the like.

The invention may be described herein in terms of functional block components, screen shots, optional selections and various processing steps. It should be appreciated that such functional blocks may be realized by any number of hardware and/or software components configured to perform the specified functions. For example, the invention may employ various integrated circuit components, e.g., memory elements, processing elements, logic elements, look-up tables, and the like, which may carry out a variety of functions under the control of one or more microprocessors or other control devices. Similarly, the software elements of the invention may be implemented with any programming or scripting language such as C, C++, JAVA, COBOL, assembler, PERL, Visual Basic, SQL Stored Procedures, extensible markup language (XML), with the various algorithms being implemented with any combination of data structures, objects, processes, routines or other programming elements. Further, it should be noted that the invention may employ any number of conventional techniques for data transmission, signaling, data processing, network control, and the like. Still further, the invention could be used to detect or prevent security issues with a client-side scripting language, such as JavaScript, VBScript or the like. For a basic introduction of cryptography and network security, see any of the following references: (1) “Applied Cryptography: Protocols, Algorithms, And Source Code In C,” by Bruce Schneier, published by John Wiley & Sons (second edition, 1995); (2) “Java Cryptography” by Jonathan Knudson, published by O'Reilly & Associates (1998); (3) “Cryptography & Network Security: Principles & Practice” by William Stallings, published by Prentice Hall; all of which are hereby incorporated by reference.

These software elements may be loaded onto a general purpose computer, special purpose computer, or other programmable data processing apparatus to produce a machine, such that the instructions that execute on the computer or other programmable data processing apparatus create means for implementing the functions specified in the flowchart block or blocks. These computer program instructions may also be stored in a computer-readable memory that can direct a computer or other programmable data processing apparatus to function in a particular manner, such that the instructions stored in the computer-readable memory produce an article of manufacture including instruction means which implement the function specified in the flowchart block or blocks. The computer program instructions may also be loaded onto a computer or other programmable data processing apparatus to cause a series of operational steps to be performed on the computer or other programmable apparatus to produce a computer-implemented process such that the instructions which execute on the computer or other programmable apparatus provide steps for implementing the functions specified in the flowchart block or blocks.

Accordingly, functional blocks of the block diagrams and flowchart illustrations support combinations of means for performing the specified functions, combinations of steps for performing the specified functions, and program instruction means for performing the specified functions. It will also be understood that each functional block of the block diagrams and flowchart illustrations, and combinations of functional blocks in the block diagrams and flowchart illustrations, can be implemented by either special purpose hardware-based computer systems which perform the specified functions or steps, or suitable combinations of special purpose hardware and computer instructions. Further, illustrations of the process flows and the descriptions thereof may make reference to user windows, web pages, web sites, web forms, prompts, etc. Practitioners will appreciate that the illustrated steps described herein may comprise in any number of configurations including the use of windows, web pages, web forms, popup windows, prompts and the like. It should be further appreciated that the multiple steps as illustrated and described may be combined into single web pages and/or windows but have been expanded for the sake of simplicity. In other cases, steps illustrated and described as single process steps may be separated into multiple web pages and/or windows but have been combined for simplicity.

Referring now to FIGS. 2-7, the interface screenshots depicted are merely embodiments of the invention and are not intended to limit the scope of the invention as described herein. For example, the steps recited in any of the interface descriptions may be executed in any order and are not limited to the order presented. It will be appreciated that the following description makes appropriate references not only to the steps and user interface elements depicted in FIGS. 2-7, but also to the various system components as described above with reference to FIG. 1.

Referring to FIG. 2, in one embodiment, user 100 begins each loan transaction by first logging into LSR 110 using secure authentication credentials such as, for example, a user ID and password combination. Practitioners will appreciate that there are a number of known and effective methods for ensuring that only those authorized to interact with the system, will be able to do so. As such, specific encryption protocols and authentication methods will not be described in greater detail herein.

After entering authentication credentials at web client 100, authentication server 125 queries user database 130 to validate the credentials and retrieve access privileges specific to the user 100. Once validated, the user may interact with the system to enter contact information for a borrower. To perform specific tasks, the interface 200 provides a control panel 205 with a variety of links. User 100 may begin to enter contact information for a new borrower by selecting a “Borrowers” link 210. Borrower contact information may include, for example, name, address, city, state, postal code, email address, social security number and the like. When all available borrower contact information has been entered, user 100 selects a “Save” link whereby the information is transmitted to web server 120 within an HTML stream where the contact data is formatted and stored within LSR database 145.

In one embodiment, user 100 may initiate an import process wherein contact and/or loan information may be imported to LSR database 145 from another application and/or database such as from a Customer Relationship Management (CRM) system. After selecting an “Import” link 215, user 100 is presented with a dialog box or a web page interface in order to define the source of the data repository to import from. Status utility 140 establishes a connection with the defined source and enters any required authentication credentials. While importing contact data, status utility 140 may employ business rules to define how the data is to be formatted and stored.

A pipeline interface enables the user to view all, or a subset of, loan applications that are currently being processed. Details regarding loans in the pipeline include, for example, the identity of the borrower, loan amount, close of escrow date, interest rate, application status, loan purpose, lender, loan type, loan officer, selling agent, listing agent, and escrow agent. Practitioners will appreciate that the level of detail and the types of information shown in the pipeline interface may vary. In one embodiment, user 100 may configure the pipeline interface to show varying levels of detail based on his or her preferences. User 100 may sort the pipeline list according to any number of criteria. For example, user 100 may select to sort the list in ascending order according to borrower name by clicking on the column header. Moreover, the system may filter the applications shown in the pipeline according to the borrower first name, last name, loan officer, status, or any other detail included in the pipeline interface.

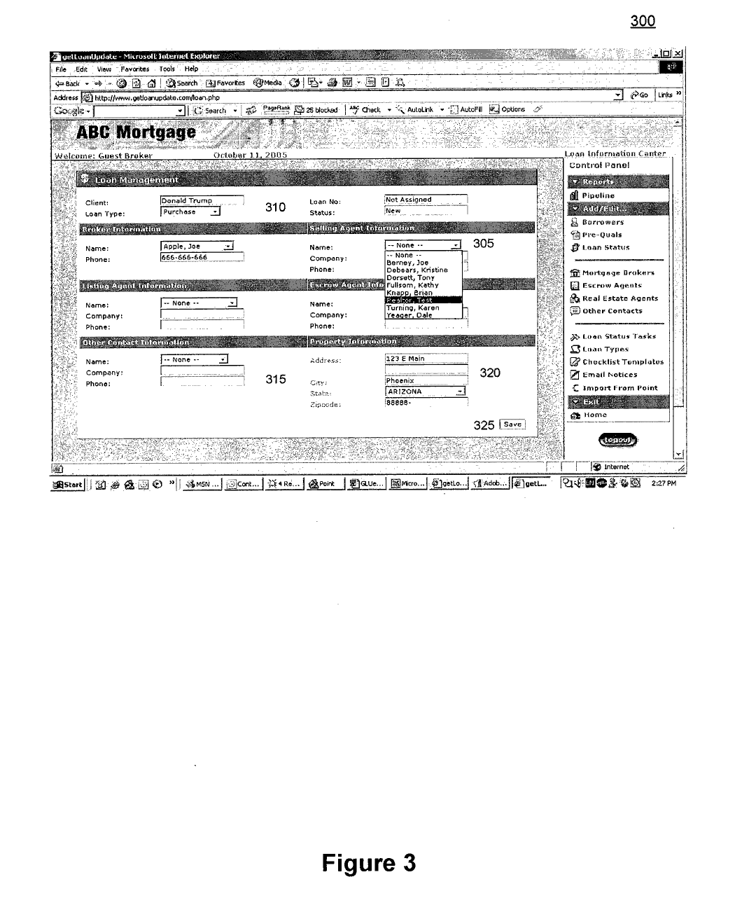

FIG. 3 is a screenshot of an exemplary interface for displaying entering and modifying loan information. When contact information has been created and stored, the user is presented with an interface 300 to enter loan details specific to the contact which is vital to future loan status reporting. The loan management interface 300 provided a number of text fields, drop-down menus and drop-down combo boxes which allow both free text entry and selection of menu items. Whenever information for a new broker, selling agent, listing agent, and/or escrow agent is entered into LSR 110, it is saved to a table which is used to automatically populate the relevant fields on subsequent selection of the broker, selling agent, listing agent, or escrow agent. Therefore, when user 100 selects a broker name from the drop-down combo box 305, status utility 140 queries LRS database 145 for all related information and sends it to the web client 105 where it populates the corresponding loan management interface 300 fields. User 100 also enters general loan information 310, additional contact information 315 and property information 320. When user 100 selects a “Save” link 325, all information is sent to LSR 110 where it is stored in LSR database 145 with the appropriate keys linking the record to corresponding contact records.

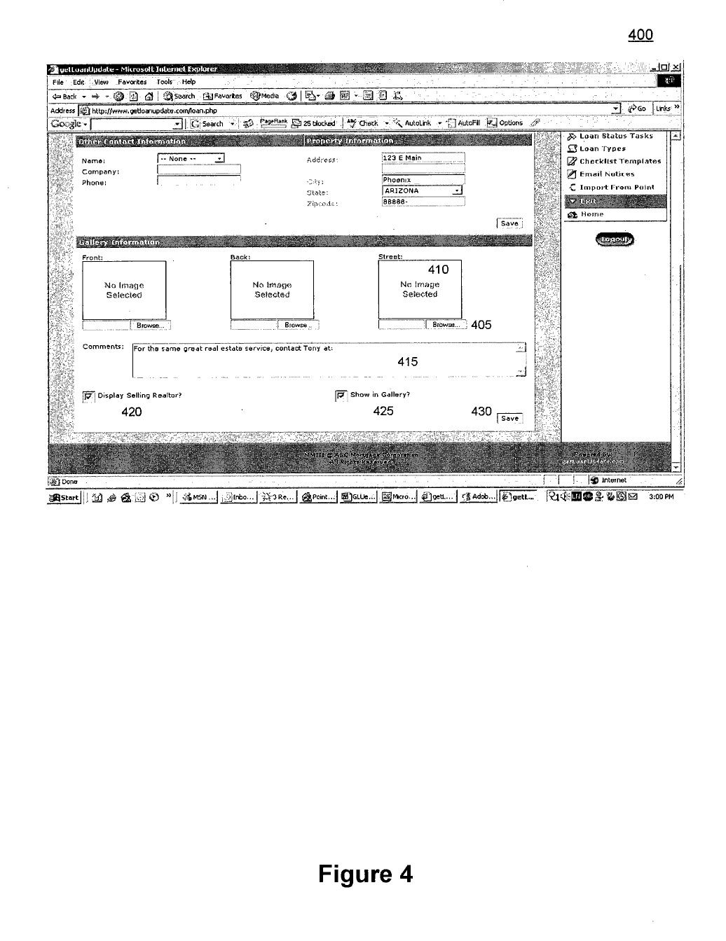

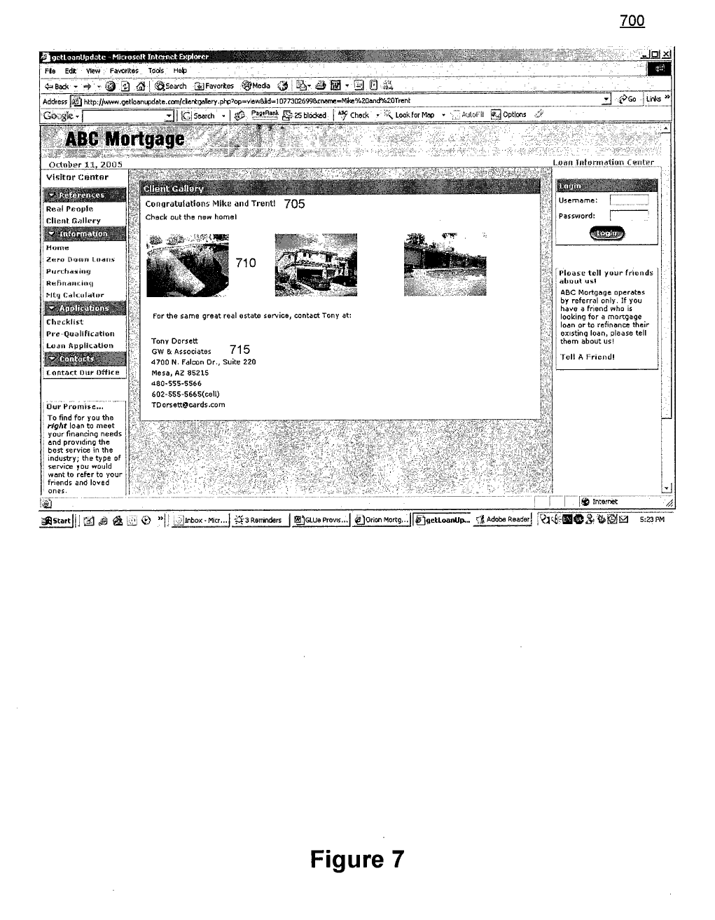

FIG. 4 is a screenshot of an exemplary interface for uploading and displaying property photograph. The photo upload interface 400 enables user 100 to upload photographs of the property for which the loan is directed. Photos may be retrieved from a variety of sources including an appraisal file or database system. When user 100 selects the “Browse” link 405, a “File Open” dialog is displayed allowing user 100 to locate a specific graphic file to upload. When a file is selected, the graphic file is uploaded to web server 120 memory transmitted to client browser 105 where it is displayed within gallery information interface 410. User 100 may optionally enter comments relating to the photographs within a comments field 415. User 100 my also select a check box 420 to indicate that the selling realtor should be identified along with any display of the uploaded property photograph. If user 100 selects a check box to show the photograph in a gallery 425, then the photograph will be made available for viewing along with other LSR 110 information, as will be discussed in greater detail in reference to FIG. 7.

When the desired photographs have been selected and comments have been entered, user 100 may select a “Save” button 430 to invoke status utility 140 to retrieve the graphics files from memory and store them within LSR database 145 where the newly created record is created with the appropriate keys linking it with the corresponding contact records. In one embodiment, status utility 140 may open a file containing the graphic image. User 100 may select the image from the file invoking status utility 140 which copies the image into memory before storing it within LSR database 145.

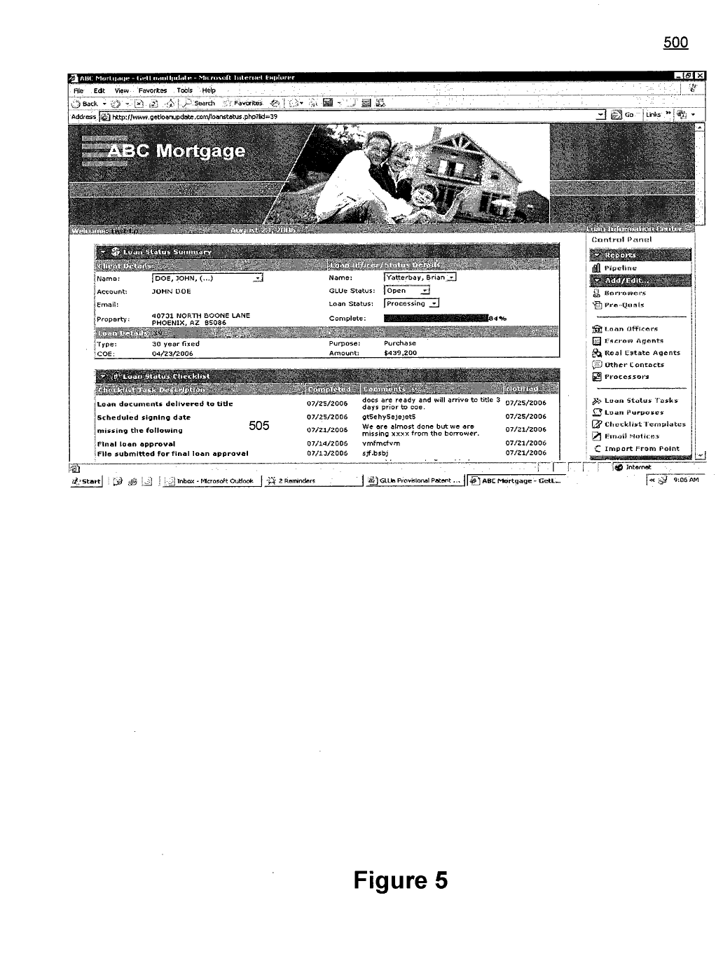

FIG. 5 is a screenshot of an exemplary interface for displaying loan processing milestones and tasks. A loan status summary and status checklist interface 500 is provided to enable user 100 to view and update task milestones. Milestones are defined and maintained within LSR database 145 and a set of business rules ensure that milestone tasks are completed in proper order and within a defined period of time. Those skilled in the art will appreciate that in any complex process incorporating a number of specific tasks; some tasks can be completed simultaneously or are not dependent on other tasks. Other tasks must be completed at very specific times in the process and may be considered a “critical path”, meaning that the completions of other tasks are dependent on the completion of the “critical path” task. Therefore, LSR 110 business rules identify critical tasks and ensure that completion of all tasks comply with the rules of the overall process while ensuring completion at the highest possible efficiency. Moreover, different business rules may be applied to different loan types. Depending on the nature of the loan, milestone tasks may vary, therefore LSR 110 employs the proper set of business rules accordingly.

The milestone checklist includes a task description, a completion date and comments in order to display any critical or helpful information relating to the specific task. The milestone checklist 505 also includes a graphic indicator to alert user 100 that although the loan record has been updated, user 100 has not yet notified all involved parties of the update. Task descriptions appear in black when they are complete and red if they are incomplete. As tasks are completed, LSR 100 includes both manual and automatic email notification features. The manual email affords user 100 more flexibility as to when a notification is sent as well as the content. The automatic notification feature allows user 100 to define a predetermined date and time for email updates to be sent to the involved parties.

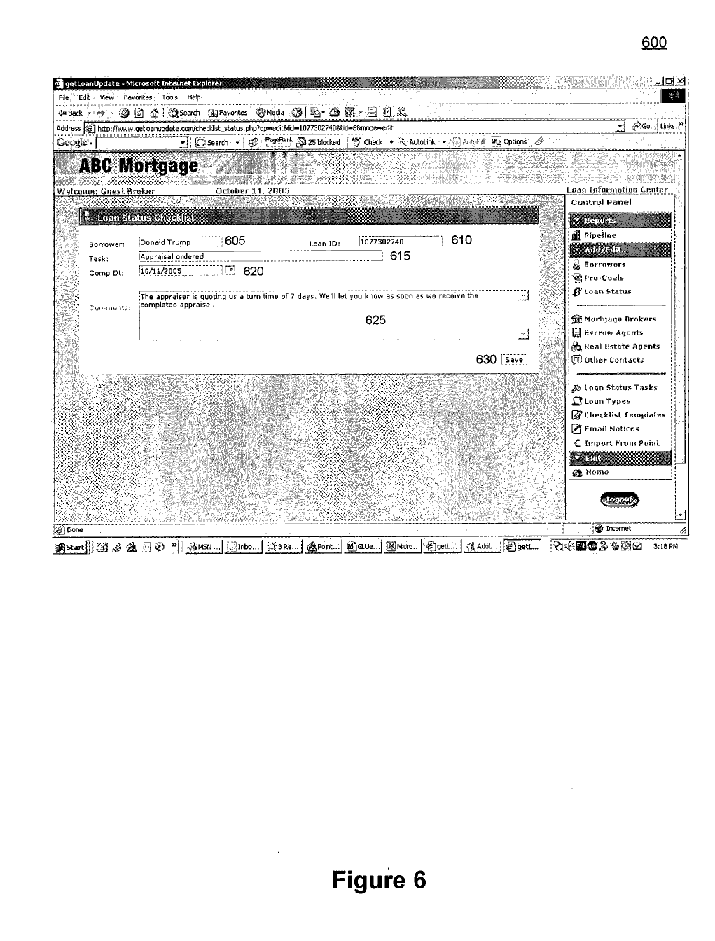

Referring to FIG. 6, the information that appears in the milestone checklist is created and/or edited through the loan status checklist interface 600. When user 100 selects an “Add/Edit” link from the loan status summary and status checklist interface 500, LSR 110 is invoked to present user 100 with the loan status checklist web page 600. Information such as the borrower name 605 and loan ID 610 may be automatically populated from LSR database 145. User 100 may enter a new task descriptor 620 or edit an existing one. If the task has been completed, user 100 may enter the completion date 620 as well as any comments 625 relating to the task. When user 100 has completed entering information in the loan status checklist 600, user 100 may select a “Save” link 630 which invokes status utility 140 to store the updated checklist item to LSR database 145 where the newly created record is created with the appropriate keys linking it with the corresponding contact records.

To generate an email notification to alert the parties of any changes to the loan status checklist 600, user 100 may select an email message from a list of templates (not illustrated). The templates are customizable and may be edited by user 100 prior to sending. When satisfied with the selected template user 100 selects a “Send” link which invokes LSR 100 to present user 100 with a “Notice Preview” screen. The “Notice Preview” screen enables user 100 to select or deselect notification recipients as well as make any desired changes to the notification prior to sending. The notification is not sent to the selected recipients until user 100 selects the “Email” link. As user 100 continues to update the loan status, a visual representation graphically charts the percentage of the transaction that has been completed.

When the notification is received by the selected recipients, the notification contains an embedded link that when selected, invokes LSR 110 to present the recipient with the loan status report page of the LSR 110 web site. In one embodiment, the embedded link contains the authentication credentials of the recipient thereby eliminating the need for the recipient to manually enter credentials at the KSR 110 web site. From the loan status report page, recipients may view, for example, the borrower's name, property address, loan status, “percentage-completed” bar graph, contact information for parties to the transaction and the loan status checklist of tasks completed and those yet to be completed.

When user 100 has completed a task for a particular loan, user 100 may view a list of other pending loans by selecting a “pipeline” link. This enables user 100 to select another loan to update and/or modify such as, for example, modifying the borrower profile or loan profile.

According to one embodiment, LST 110 includes a notification template that borrowers may use as a means to announce their new home purchase to friends & family. As described in reference to FIG. 4, user 100 may upload a number of photos of the loan property from an appraisal report or any other source. Referring to FIG. 7, at any point during loan processing, user 100 may send a notification template via email to the borrower and suggest they forward the notification to their friends and family. The notification may be manually generated by user 100 in order to personalize the template or may be automatically generated when loan processing reaches a predefined state of completion. The notification includes a link to a “Client Gallery” web page 700 on the LSR 110 web site. The “Client Gallery” web page 700 may include a personalized message 705, property photographs 710, property address as well as cross-marketing information 715 such as, for example, an endorsement of their realtor. Web page 700 may further include photos of the client's realtor, escrow agent, or any other third party with an interest in the loan property.

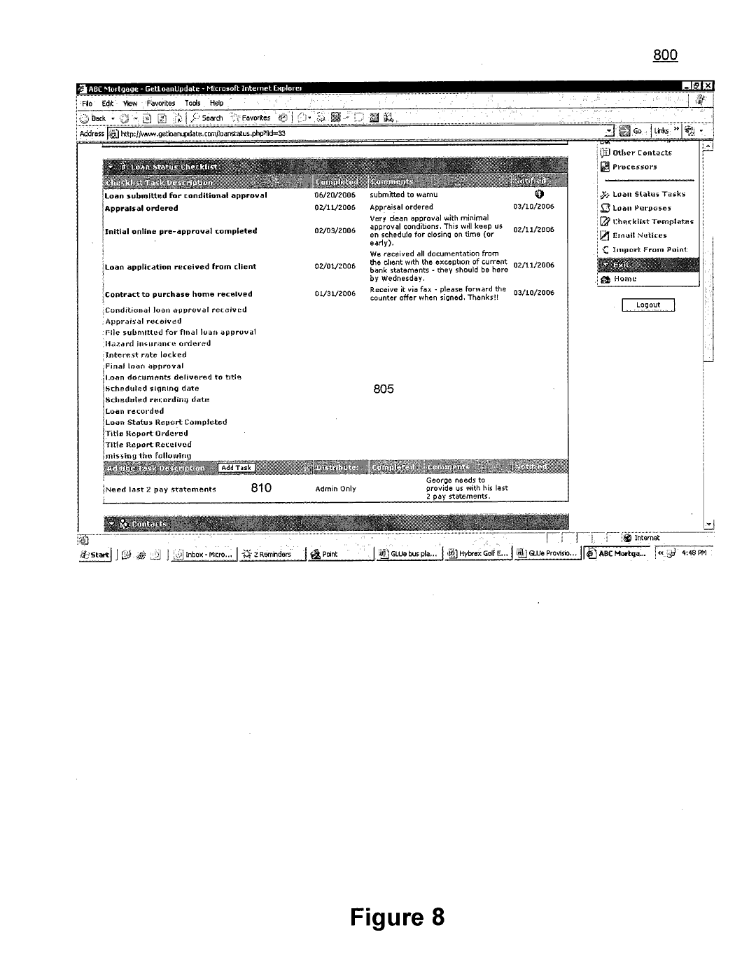

Referring to FIG. 8, the LSR 110 may provide any number of pre-defined task descriptions in order to simplify the step of adding a task. Most mortgage lenders have a unique workflow which defines rules about how and when each task relevant to application processing is performed relative to specific events. For example, a mortgage lender may hold a loan application from entering processing until certain other documents are received. When each document is received, a corresponding task is recorded as complete. When each of the required documents has been received, then the application in moved forward over a series of tasks which may themselves rely on the completion of other tasks. Therefore, the system enables the administrator to configure standard checklist templates which define all of the tasks that need to take place during application processing. In one embodiment, the system may be preconfigured with a list of templates that are applicable to varying types of loans. However, circumstances do arise from time-to-time that requires the addition of one or more additional tasks that are not part of the checklist template.

Exemplary tasks include the tasks listed in FIG. 8. Other tasks and rules may include, for example, sending loan documents to the title company, obtaining signatures, obtaining credit approval, obtaining an appraisal, obtaining community homeowner association disclosures and the like.

To add a new task description, user 100 selects an “Add Task” link 810, which opens a new window with fields to enable user 100 to enter the task description, a distribution mode, comments, and the like. The distribution mode defines to whom within the organization the task should be distributed or assigned. To maintain the integrity of the system, the addition of one or more tasks to a particular loan application does not result in the modification of the checklist template. On indicating that the task description and other relevant fields are complete, the task is entered to the loan status checklist 810. To ensure that the task is not integrated with the template tasks, the added task may be displayed separately from the template tasks 805.

LSR 100 provides various other online tools and resources to help borrowers, loan processors and any other third-party execute the loan process in a convenient, informed and efficient manner. Such tools include, for example a mortgage calculator, a process checklist, a mortgage pre-qualification form, and mortgage application. Information resources such as a client testimonial web page, links to articles of interest and links to contact a loan processor are also provided to both keep the borrower informed and to attract a prospective borrower to the mortgage lender unitizing LSR 110. In one embodiment, documents relevant to loan processing are digitally stored in a repository, such as in LSR database 145. Documents such as, for example, loan applications, sales contracts, and appraisals may be scanned or photographed and stored in LSR database 145 with a key corresponding to a client record. A link may be added to relevant portions of the web interfaces to enable user 100 to view a digitized document.

Benefits, other advantages, and solutions to problems have been described herein with regard to specific embodiments. However, the benefits, advantages, solutions to problems, and any element(s) that may cause any benefit, advantage, or solution to occur or become more pronounced are not to be construed as critical, required, or essential features or elements of any or all the claims or the invention. Further, no element described herein is required for the practice of the invention unless expressly described as “essential” or “critical”.

We claim:

1. A computer implemented method for managing and communicating application processing tasks comprising:
retrieving client data and transaction data from a database to create application data;
applying a workflow template based on said application data, wherein said workflow template defines a plurality of tasks for processing a transaction application, and wherein each of said plurality of tasks correspond to a business rule;
determining a first task due from said plurality of tasks according to said workflow template, and identifying a first user who is responsible to perform said first task;
notifying said first user of said first task;
determining a second task due from said plurality of tasks according to said workflow template, and identifying a second user who is responsible to perform said second task;
notifying said second user of said second task;
receiving notice from said first user when said first task is complete; and,
receiving notice from said second user when said second task is complete.

2. The method of claim 1, wherein said retrieving step comprises retrieving client data into said database from a customer relationship management (CRM) system.

3. The method of claim 1, further comprising a user entering said transaction data in relation to said client data.

4. The method of claim 1, wherein said client data includes at least one of name, spouse name, residence address, city, state, postal code, telephone number, employer, employer address, employer phone, email address, and social security number.

5. The method of claim 1, wherein said transaction data includes at least one of property data, credit data, debt data, loan amount, close of escrow date, interest rate, application status, loan purpose, lender, loan type, loan officer, selling agent, listing agent, and escrow agent.

6. The method of claim 1, further comprising listing a plurality of in-process transactions, wherein each of said plurality of in-process transactions includes at least one of client identity, loan amount, close of escrow, interest rate, application status, loan purpose, lender, loan type, loan officer, selling agent, listing agent, and escrow agent.

7. The method of claim 6, wherein said plurality of in-process transactions are sorted according to at least one of said client identity, said loan amount, said close of escrow, said interest rate, said application status, said loan purpose, said lender, said loan type, said loan officer, said selling agent, said listing agent, and said escrow agent.

8. The method of claim 1, further comprising providing a transaction processing interface displaying at least one of milestones and tasks.

9. The method of claim 1, wherein said business rule defines at least one of an order for each of said plurality of tasks to be completed and a time threshold for each of said plurality of tasks to be completed.

10. The method of claim 1, further comprising providing a graphic indicator showing the percentage of said plurality of tasks that have been completed.

11. The method of claim 1, wherein said notifying steps comprise an email message that is generated at least one of automatically and manually.

12. The method of claim 11, wherein said email message includes a hyperlink to a transaction status report.

13. The method of claim 1, further comprising generating a notification web page comprising at least one of a digital image of a property, a property address, and cross-marketing information.

14. The method of claim 13, wherein said digital image is received from at least one of a database and an appraisal file.

15. The method of claim 13, wherein said user enters comments corresponding to said digital image.

16. The method of claim 1, further comprising providing an application modification interface wherein said application data is at least one of entered and modified.

17. The method of claim 16, wherein application data is saved to a lookup table.

18. The method of claim 1, wherein said client data comprises at least one of borrower data, builder client data, title company client data, realtor client data, broker client data, banker client data, wholesale borrower data, and appraiser client data.

19. The method of claim 1, wherein said transaction data includes at least one of loan data, builder data, title company data, realtor data, broker data, banker data, wholesale lender data, and appraiser data.

20. A machine-readable medium having stored thereon a plurality of instructions, the plurality of instructions when executed by a processor, cause the processor to perform a method comprising the steps of:
retrieving client data and transaction data from a database to create application data;
applying a workflow template based on said application data, wherein said workflow template defines a plurality of tasks for processing a transaction application, and wherein each of said plurality of tasks correspond to a business rule;
determining a first task due from said plurality of tasks according to said workflow template, and identifying a first user who is responsible to perform said first task;
notifying said first user of said first task;
determining a second task due from said plurality of tasks according to said workflow template, and identifying a second user who is responsible to perform said second task;
notifying said second user of said second task;
receiving notice from said first user when said first task is complete; and,
receiving notice from said second user when said second task is complete.
